(19) United States
(12) Patent Application Publication
(10) Pub. No.: US 2026/0171131 A1
(43) Pub. Date: Jun. 18, 2026

(54) SEMICONDUCTOR DEVICE AND METHOD FOR CONTROLLING THE SAME

(71) Applicant: Renesas Electronics Corporation, Tokyo (JP)

(72) Inventor: Akira MOTOSU, Tokyo (JP)

(21) Appl. No.: 19/423,023

(22) Filed: Dec. 17, 2025

(30) Foreign Application Priority Data
Dec. 18, 2024 (JP) 2024-221674

(51) Int. Cl. G11C 11/16

(52) U.S. Cl. CPC G11C 11/1697; G11C 11/1659; G11C 11/1673

(57) ABSTRACT

According to the present disclosure, a semiconductor device includes a first electronic circuit including a first semiconductor element group having a first threshold voltage, and a second semiconductor element group having a second threshold voltage higher than the first threshold voltage, a second electronic circuit having a same logical configuration as the first electronic circuit, and in which a ratio occupied by the second semiconductor element group among the first semiconductor element group and the second semiconductor element group is greater than that in the first electronic circuit, a power supply connection portion that connects one of the first electronic circuit and the second electronic circuit to a power supply, a storage unit that stores power supply connection information, and a control circuit that controls the power supply connection portion to connect the power supply to one of the first electronic circuit and the second electronic circuit selected based on the power supply connection information read from the storage unit.

### CROSS-REFERENCE TO RELATED APPLICATIONS

The disclosure of Japanese Patent Application No. 2024-221674 filed on Dec. 18, 2024 including the specification, drawings and abstract is incorporated herein by reference in its entirety.

### BACKGROUND

The present disclosure relates to a semiconductor device and a method for controlling the same, and relates, for example, to a semiconductor device and a method for controlling the same that are capable of implementing high-speed operation while reducing leakage current.

There are disclosed techniques listed below.

[Patent Document 1] Japanese Unexamined Patent Application Publication No. 2011-238082

Patent Document 1 discloses a technique relating to a computer system including a dual-core microcomputer that is switchable between a performance mode operating in parallel and a safety mode operating with duplicated comparison. The computer system can set one or a plurality of CPUs to be interrupted for each interrupt factor. In addition, the computer system can set, for each interrupt factor, whether execution is performed in the performance mode or in the safety mode.

In addition, in recent years, with the miniaturization of semiconductor processes, development has been advanced on semiconductor devices capable of implementing high-speed operation by using a large number of semiconductor elements having a low threshold voltage.

### SUMMARY

However, when attempting to increase the processing speed of the semiconductor device, there has been a problem in that leakage current becomes large, particularly under high-temperature conditions. Other objects and novel features will become apparent from the description of this specification and the accompanying drawings.

According to the present disclosure, a semiconductor device includes a first electronic circuit including a first semiconductor element group having a first threshold voltage, and a second semiconductor element group having a second threshold voltage higher than the first threshold voltage, a second electronic circuit having a same logical configuration as the first electronic circuit, and in which a ratio occupied by the second semiconductor element group among the first semiconductor element group and the second semiconductor element group is greater than that in the first electronic circuit, a power supply connection portion that connects one of the first electronic circuit and the second electronic circuit to a power supply, a storage unit that stores power supply connection information, and a control circuit that controls the power supply connection portion to connect the power supply to one of the first electronic circuit and the second electronic circuit selected based on the power supply connection information read from the storage unit.

According to the present disclosure, a method for controlling a semiconductor device, in which the semiconductor device includes a first electronic circuit including a first semiconductor element group having a first threshold voltage, and a second semiconductor element group having a second threshold voltage higher than the first threshold voltage, and a second electronic circuit having a same logical configuration as the first electronic circuit, and in which a ratio occupied by the second semiconductor element group among the first semiconductor element group and the second semiconductor element group is greater than that in the first electronic circuit, and the method for controlling the semiconductor device includes reading out power supply connection information stored in a storage unit, and connecting one of the first electronic circuit and the second electronic circuit selected based on the read power supply connection information to a power supply.

According to the present disclosure, a computer readable storage medium for control that causes a computer to execute control processing of a semiconductor device includes a first electronic circuit including a first semiconductor element group having a first threshold voltage, and a second semiconductor element group having a second threshold voltage higher than the first threshold voltage, and a second electronic circuit having a same logical configuration as the first electronic circuit, and in which a ratio occupied by the second semiconductor element group among the first semiconductor element group and the second semiconductor element group is greater than that in the first electronic circuit, and the computer readable storage medium for control causes the computer to execute processes of reading out power supply connection information stored in a storage unit, and connecting one of the first electronic circuit and the second electronic circuit selected based on the read power supply connection information to a power supply.

The present disclosure can provide a semiconductor device capable of implementing high-speed operation while suppressing leakage current and a method for controlling the same.

### BRIEF DESCRIPTION OF THE DRAWINGS

FIG. 1 is a block diagram illustrating a configuration example of a semiconductor device in a conceptual stage.

FIG. 2 is a block diagram illustrating a configuration example of a semiconductor device according to a first embodiment.

FIG. 3 is a flowchart illustrating a method of replacing logic cells.

FIG. 4 is a diagram illustrating the method of replacing the logic cells.

FIG. 5 is a block diagram illustrating a configuration example of a semiconductor device in a conceptual stage.

FIG. 6 is a block diagram illustrating a configuration example of a semiconductor device according to a second embodiment.

### DETAILED DESCRIPTION

The embodiments will be described below with reference to the drawings. It should be noted that the drawings are simplified, and therefore the technical scope of the embodiments must not be construed narrowly based on the illustration of the drawings. The same reference numerals are given to the same elements, and redundant descriptions are omitted.

In the following embodiments, for convenience, when necessary, the description will be divided into a plurality of sections or embodiments. However, unless otherwise explicitly stated, they are not independent of each other, but one is related to the other as a modification, an application, a detailed description, or a supplementary description of a part or the whole. Further, in the following embodiments, when referring to the number of elements (including the number, numerical values, amounts, ranges, and the like), unless otherwise explicitly stated or unless it is apparent in principle that the number is limited to a specific value, the number is not limited to the specific value, and may be equal to or greater than or less than the specific value.

Furthermore, in the following embodiments, the constituent elements (including operation steps and the like) are not necessarily essential, unless otherwise explicitly stated or unless it is apparent in principle that they are essential. Similarly, in the following embodiments, when referring to the shapes or positional relationships of constituent elements and the like, unless otherwise explicitly stated or unless it is apparent in principle that they are not so, the description shall be construed to include those substantially approximating or similar to such shapes or the like. The same applies to the above-mentioned numbers (including the number, numerical values, amounts, ranges, and the like).

### Semiconductor Device 50 in Conceptual Stage Before First Embodiment

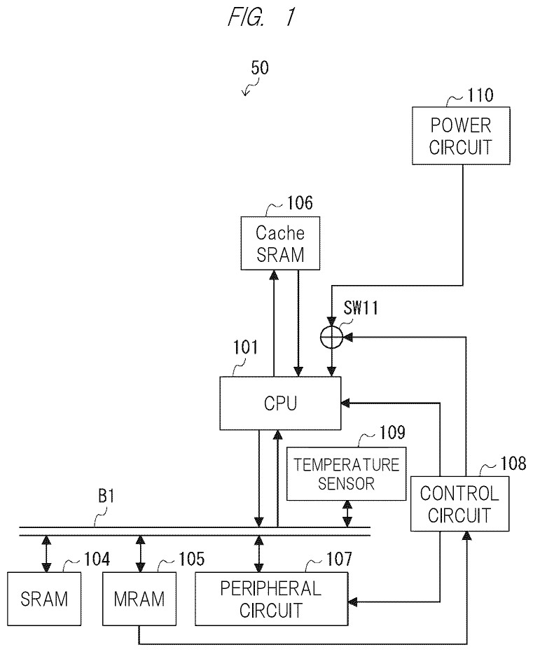

FIG. 1 is a block diagram illustrating a configuration example of a semiconductor device 50 in a conceptual stage. The semiconductor device 50 is, for example, a Microcontroller Unit (MCU).

Specifically, the semiconductor device 50 includes a Central Processing Unit (CPU) 101, a Static Random Access Memory (SRAM) 104, a Magnetoresistive Random Access Memory (MRAM) 105, a cache SRAM 106, a peripheral circuit 107, a control circuit 108, a temperature sensor 109, a power supply circuit 110, a bus B1, and a switch SW11.

The CPU 101 is connected, via the bus B1, to the SRAM 104, the MRAM 105, the peripheral circuit 107, and the temperature sensor 109. The cache SRAM 106 is directly connected to the CPU 101 without intermediation by the bus B1. The switch SW11 is provided between the power supply circuit 110 and the CPU 101, and switches on and off based on a control signal from the control circuit 108.

The SRAM 104 and the cache SRAM 106 are a type of volatile memory and store programs and the like executed by the CPU 101. The CPU 101 is an arithmetic processing circuit that sequentially executes instructions of programs stored in the SRAM 104, the cache SRAM 106, or the MRAM 105. The temperature sensor 109 detects the temperature of the semiconductor device 50. More specifically, the temperature sensor 109 detects the temperature of the CPU 101. The peripheral circuit 107 operates in cooperation with the CPU 101. The peripheral circuit 107 may include an analog circuit and a communication circuit that performs communication with the outside. The MRAM 105 is a type of nonvolatile memory and stores programs executed by the CPU 101, trimming information of the analog circuit provided in the peripheral circuit 107, and the like.

The control circuit 108, for example, places the CPU 101 and the peripheral circuit 107 into a reset state based on a reset signal (not illustrated) supplied to a reset terminal of the semiconductor device 50 or an instruction from the CPU 101, and then, after performing initial setting of the peripheral circuit 107 based on trimming information and the like read from the MRAM 105, releases the reset of the CPU 101 and the peripheral circuit 107 and supplies a clock signal, thereby operating the entire system of the semiconductor device 50. In addition, when an operation mode is set to a standby mode, which is a mode that stops at least part of the operation of the semiconductor device 50 to reduce power consumption, the control circuit 108 switches the switch SW11 from on to off, thereby stopping the power supply from the power supply circuit 110 to the CPU 101. Thereafter, until a specific wake-up factor is input, the control circuit 108 maintains the switch SW11 in the off state.

The CPU 101 is configured using a plurality of logic cells having a threshold voltage of LVt (hereinafter referred to as LVt cells) and a plurality of logic cells having a threshold voltage of HVt (hereinafter referred to as HVt cells). It should be noted that LVt<HVt. For example, LVt is 0.3 V, and HVt is 0.5 V.

The LVt cell is configured using a plurality of MOS transistors having a threshold voltage of LVt. Accordingly, with the LVt cells, the operation speed is high (the time required from input to output is short), but leakage current becomes large. It should be noted that the LVt cell is not limited to being configured using a plurality of MOS transistors having a threshold voltage of LVt, but may be configured using a plurality of semiconductor elements that switches between conduction and nonconduction from one terminal to another based on whether a control voltage is equal to or higher than the threshold voltage LVt.

In contrast, the HVt cell is configured using a plurality of MOS transistors having a threshold voltage of HVt. Accordingly, with the HVt cells, the operation speed is low (the time required from input to output is long), but leakage current becomes small. It should be noted that the HVt cell is not limited to being configured using a plurality of MOS transistors having a threshold voltage of HVt, but may be configured using a plurality of semiconductor elements that switches between conduction and nonconduction from one terminal to another based on whether a control voltage is equal to or higher than the threshold voltage HVt.

Here, the CPU 101 is configured using more LVt cells than HVt cells in order to implement high-speed operation. In other words, the CPU 101 is configured using more MOS transistors having a threshold voltage of LVt than MOS transistors having a threshold voltage of HVt. Accordingly, in the CPU 101, the operation speed is high (that is, the maximum operating frequency is large), but leakage current becomes large. Particularly, due to recent miniaturization of processes, leakage current becomes remarkably large as the temperature increases. However, in the CPU 101 in which the LVt cells are dominant, even if the operating frequency is lowered at high temperature, only the dynamic current associated with switching is reduced, and the remarkably increased leakage current is not reduced. Accordingly, the CPU 101 is suitable for high-speed operation under low-temperature conditions, but may not be suitable for operation with low power consumption under high-temperature conditions. In the present disclosure, an example will be described in which the maximum operating frequency of the CPU 101 is 800 MHz.

Thus, the semiconductor device 50 at the conceptual stage can implement high-speed operation under low-temperature conditions, but has a problem in that leakage current increases particularly under high-temperature conditions. Accordingly, a semiconductor device 1 according to the present disclosure has been provided, which solves such a problem, and which can implement high-speed operation under low-temperature conditions while reducing leakage current particularly under high-temperature conditions.

### First Embodiment

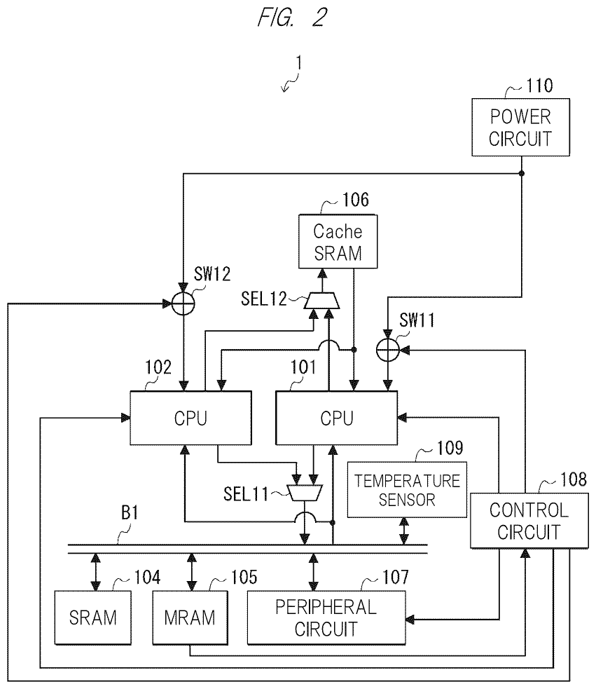

FIG. 2 is a block diagram illustrating a configuration example of a semiconductor device 1 according to a first embodiment. The semiconductor device 1 is, for example, an MCU.

The semiconductor device 1 further includes a CPU 102, selectors SEL11 and SEL12, and a switch SW12, in comparison with the semiconductor device 50. Specifically, the semiconductor device 1 includes a CPU (first electronic circuit) 101, a CPU (second electronic circuit) 102, an SRAM 104, an MRAM 105, a cache SRAM 106, a peripheral circuit 107, a control circuit 108, a temperature sensor 109, a power supply circuit (power supply) 110, a bus B1, selectors SEL11 and SEL12, and switches SW11 and SW12.

The CPU 102 has the same logical configuration as the CPU 101. The CPU 102, similarly to the CPU 101, is configured using a plurality of LVt cells and a plurality of HVt cells. However, a ratio occupied by the HVt cells among the plurality of logic cells used in the CPU 102 is greater than that in the CPU 101. Therefore, the CPU 102 operates at a lower speed than the CPU 101 (that is, the maximum operating frequency of the CPU 102 is smaller than that of the CPU 101), but leakage current is smaller than that of the CPU 101. As a result, in the CPU 102, the increase in leakage current, which becomes significant as the temperature rises, is suppressed. In the present disclosure, an example in which the maximum operating frequency of the CPU 102 is 400 MHz will be described.

The switch SW11 is provided between the power supply circuit 110 and the CPU 101, and switches on and off based on a control signal from the control circuit 108. The switch SW12 is provided between the power supply circuit 110 and the CPU 102, and switches on and off based on a control signal from the control circuit 108. The switches SW11 and SW12 constitute a power supply connection portion, and are complementarily switched on and off based on the control signals from the control circuit 108 when an operation mode is a normal operation mode, and are both switched off based on the control signals from the control circuit 108 when the operation mode is a standby mode.

The selector SEL11 selects either a signal from the CPU 101 to the bus B1 or a signal from the CPU 102 to the bus B1, and outputs the selected signal to the bus B1. A signal from the bus B1 is input to both the CPU 101 and the CPU 102. The selector SEL12 selects either a signal from the CPU 101 to the cache SRAM 106 or a signal from the CPU 102 to the cache SRAM 106, and outputs the selected signal to the cache SRAM 106. A signal from the cache SRAM 106 is input to both the CPU 101 and the CPU 102.

In addition to programs executed by the CPU 101 and trimming information of an analog circuit, the MRAM 105 stores frequency setting information. Here, the frequency setting information refers to information of the maximum operating frequency required for a CPU. The frequency setting information can also be referred to as power supply connection information that determines which of the CPU 101 and the CPU 102 is connected to the power supply circuit 110.

The control circuit 108, for example, places the CPU 101, the CPU 102, and the peripheral circuit 107 in a reset state based on a reset signal (not illustrated) supplied to a reset terminal of the semiconductor device 50, or based on an instruction from one of the CPU 101 and the CPU 102 connected to the power supply circuit 110, and then performs initial setting of the peripheral circuit 107 based on the trimming information and the like read from the MRAM 105, and connects the power supply circuit 110 to one of the CPU 101 and the CPU 102 based on the frequency setting information read from the MRAM 105. Specifically, the control circuit 108 outputs a control signal corresponding to the frequency setting information read from the MRAM 105 to the switches SW11 and SW12 and the selectors SEL11 and SEL12. As a result, the switches SW11 and SW12 connect the CPU among the CPU 101 and the CPU 102 corresponding to the frequency setting information to the power supply circuit 110. In addition, the selectors SEL11 and SEL12 connect signal lines between the CPU connected to the power supply circuit 110 and the bus B1 and the cache SRAM 106. Thereafter, the control circuit 108 releases the reset of the CPU connected to the power supply circuit 110 and the peripheral circuit 107 and supplies a clock signal, thereby operating a system of the semiconductor device 1.

When the operation mode is set to the standby mode, the control circuit 108 stops power supply from the power supply circuit 110 to the CPU 101 and the CPU 102 by switching the switches SW11 and SW12 from on to off. Thereafter, until a specific wake-up factor is input, the control circuit 108 maintains the switches SW11 and SW12 in the off state.

In the present disclosure, the maximum operating frequency of the CPU 101 is 800 MHz, and the maximum operating frequency of the CPU 102 is 400 MHz. Therefore, when 800 MHz is set as frequency setting information in the MRAM 105, the control circuit 108 controls the switch SW11 to turn on and controls the switch SW12 to turn off. That is, the power supply connection portion including the switches SW11 and SW12 selects the CPU 101 as a connection destination of the power supply circuit 110. As a result, a power supply voltage is supplied from the power supply circuit 110 to the CPU 101. At this point, the selector SEL11 selects, from among a signal from the CPU 101 to the bus B1 and a signal from the CPU 102 to the bus B1, the signal from the CPU 101 selected as the connection destination of the power supply circuit 110, and outputs the selected signal to the bus B1. In addition, the selector SEL12 selects, from among a signal from the CPU 101 to the cache SRAM 106 and a signal from the CPU 102 to the cache SRAM 106, the signal from the CPU 101 selected as the connection destination of the power supply circuit 110, and outputs the selected signal to the cache SRAM 106.

In contrast, when 400 MHz is set as frequency setting information in the MRAM 105, the control circuit 108 controls the switch SW11 to turn off and controls the switch SW12 to turn on. That is, the power supply connection portion including the switches SW11 and SW12 selects the CPU 102 as a connection destination of the power supply circuit 110. As a result, a power supply voltage is supplied from the power supply circuit 110 to the CPU 102. At this point, the selector SEL11 selects, from among a signal from the CPU 101 to the bus B1 and a signal from the CPU 102 to the bus B1, the signal from the CPU 102 selected as the connection destination of the power supply circuit 110, and outputs the selected signal to the bus B1. In addition, the selector SEL12 selects, from among a signal from the CPU 101 to the cache SRAM 106 and a signal from the CPU 102 to the cache SRAM 106, the signal from the CPU 102 selected as the connection destination of the power supply circuit 110, and outputs the selected signal to the cache SRAM 106.

### Method of Replacing Logic Cells

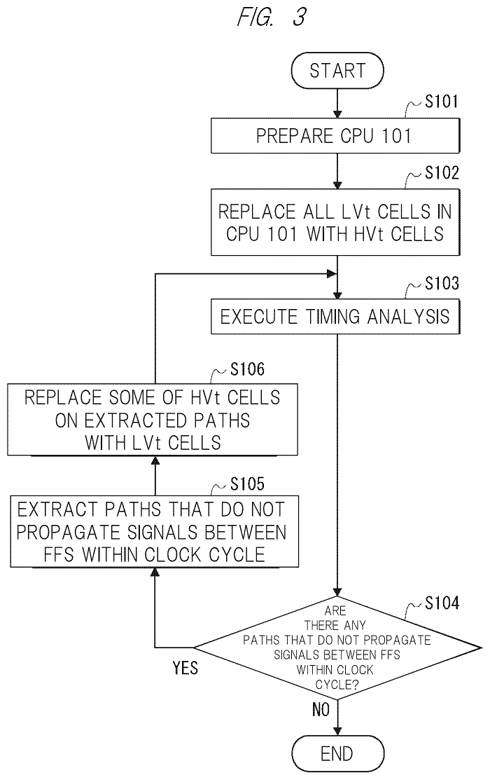

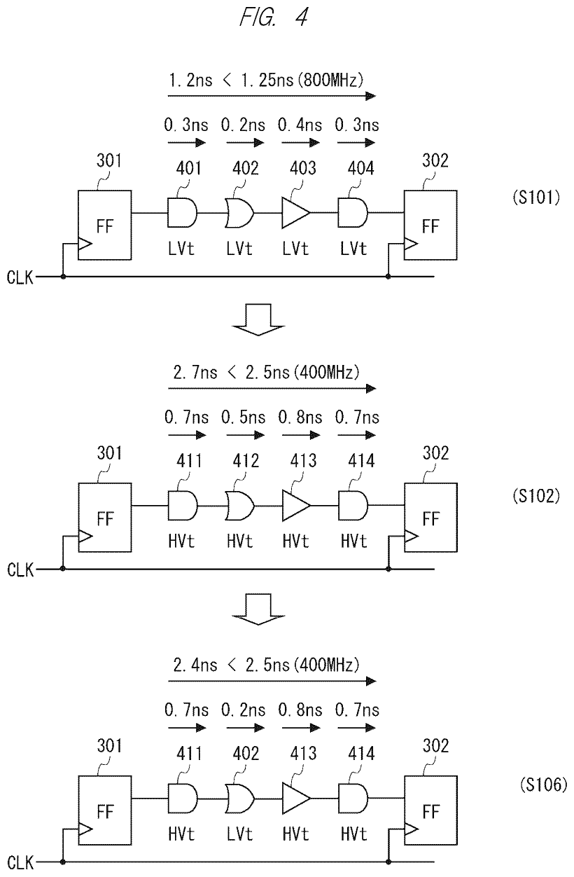

With reference to FIGS. 3 and 4, a method of forming a logical configuration of the CPU 102 by replacing a part of the plurality of LVt cells used in the CPU 101 with the HVt cells will be described. FIG. 3 is a flowchart illustrating a method of replacing logic cells. FIG. 4 is a diagram illustrating the method of replacing the logic cells.

First, the CPU 101 is prepared (Step S101). Preparing the CPU 101 means, for example, preparing a logical configuration of the CPU 101 in a logic design environment.

In an upper diagram of FIG. 4, as a part of a circuit of the CPU 101, flip-flops 301 and 302 and logic cells 401 to 404 which are LVt cells are illustrated. The logic cell 401 is a logical AND circuit, the logic cell 402 is a logical OR circuit, the logic cell 403 is a buffer circuit, and the logic cell 404 is a logical AND circuit.

In addition, in the upper diagram of FIG. 4, a result of timing analysis when the CPU 101 is operated at the maximum operating frequency of 800 MHz is illustrated. In the example of the upper diagram of FIG. 4, a signal propagation time from the flip-flop 301 through the logic cells 401 to 404 to the flip-flop 302 needs to be 1.25 ns (=1/800 MHz) or less. However, for simplification of description, wiring delay, setup time constraint, and hold time constraint are not considered. Here, in the example of the upper diagram of FIG. 4, a delay time of the logic cell 401 is 0.3 ns, a delay time of the logic cell 402 is 0.2 ns, a delay time of the logic cell 403 is 0.4 ns, and a delay time of the logic cell 404 is 0.3 ns, and since the signal propagation time is 1.2 ns, which is less than or equal to 1.25 ns, a timing constraint is satisfied.

Thereafter, all the LVt cells used in the CPU 101 are replaced with HVt cells (Step S102). Hereinafter, the CPU 101 in which all the LVt cells have been replaced with HVt cells is referred to as CPU 101a.

In a middle diagram of FIG. 4, as a part of a circuit of the CPU 101a, the flip-flops 301 and 302 and logic cells 411 to 414 which are HVt cells are illustrated. That is, in the example of the middle diagram of FIG. 4, the logic cells 401 to 404, which are LVt cells in the circuit illustrated in the upper diagram of FIG. 4, are replaced with the logic cells 411 to 414, which are HVt cells.

Thereafter, timing analysis is performed when the CPU 101a is operated at the maximum operating frequency of the CPU 102, that is, 400 MHz (Step S103).

As a result of the timing analysis, when there is a path that does not satisfy a timing constraint (YES in Step S104), the path that does not satisfy the timing constraint is extracted (Step S105), and a part of the plurality of HVt cells arranged on the extracted path is replaced with an LVt cell (Step S106). It is noted that, in order to satisfy the timing constraint, all the HVt cells arranged on the extracted path may be replaced with LVt cells. However, it is preferable that the replacement from HVt cells to LVt cells be as few as possible within a range that satisfies the timing constraint.

In the middle diagram of FIG. 4, a result of timing analysis when the CPU 101a is operated at the maximum operating frequency of the CPU 102, that is, 400 MHz, is illustrated. In the example of the middle diagram of FIG. 4, a signal propagation time from the flip-flop 301 through the logic cells 411 to 414 to the flip-flop 302 needs to be 2.5 ns (=1/400 MHz) or less. However, for simplification of description, wiring delay, setup time constraint, and hold time constraint are not considered. Here, in the example of the middle diagram of FIG. 4, a delay time of the logic cell 411 is 0.7 ns, a delay time of the logic cell 412 is 0.5 ns, a delay time of the logic cell 413 is 0.8 ns, and a delay time of the logic cell 414 is 0.7 ns, and since the signal propagation time is 2.7 ns, which is greater than 2.5 ns, the timing constraint is not satisfied.

Accordingly, in order to satisfy the timing constraint, a part of the plurality of HVt cells used in the CPU 101a is replaced with an LVt cell (Steps S105 to S106). Hereinafter, the CPU 101a in which a part of the HVt cells has been replaced with an LVt cell is referred to as CPU 101b.

In a lower diagram of FIG. 4, as a part of a circuit of the CPU 101b, the flip-flops 301 and 302, the logic cell 411 which is an HVt cell, the logic cell 402 which is an LVt cell, the logic cell 413 which is an HVt cell, and the logic cell 414 which is an HVt cell are illustrated. That is, in the example of the lower diagram of FIG. 4, the logic cell 412 which is an HVt cell in the circuit illustrated in the middle diagram of FIG. 4 is replaced with the logic cell 402 which is an LVt cell.

Thereafter, timing analysis is performed when the CPU 101b is operated at the maximum operating frequency of the CPU 102, that is, 400 MHz (Step S103).

As a result of the timing analysis, when there is a path that does not satisfy a timing constraint (YES in Step S104), the path that does not satisfy the timing constraint is extracted (Step S105), and a part of the plurality of HVt cells arranged on the extracted path is replaced with an LVt cell (Step S106). When all the paths satisfy the timing constraint (NO in Step S104), replacement of logic cells is completed.

In the lower diagram of FIG. 4, a result of timing analysis when the CPU 101b is operated at the maximum operating frequency of the CPU 102, that is, 400 MHz, is illustrated. In the example of the lower diagram of FIG. 4, a signal propagation time from the flip-flop 301 through the logic cells 411, 402, 413, and 414 to the flip-flop 302 needs to be 2.5 ns or less. However, for simplification of description, wiring delay, setup time constraint, and hold time constraint are not considered. Here, in the example of the lower diagram of FIG. 4, a delay time of the logic cell 411 is 0.7 ns, a delay time of the logic cell 402 is 0.2 ns, a delay time of the logic cell 413 is 0.8 ns, and a delay time of the logic cell 414 is 0.7 ns, and since the signal propagation time is 2.4 ns, which is less than or equal to 2.5 ns, the timing constraint is satisfied.

The CPU 101b in which all the timing constraints are satisfied is used as the CPU 102. In other words, a logical configuration of the CPU 101b in which all the timing constraints are satisfied is used as a logical configuration of the CPU 102.

In this manner, the CPU 102 is formed from the CPU 101 by replacing as many LVt cells used in the CPU 101 as possible with the HVt cells.

### Method of Dynamically Switching Between CPU 101 and CPU 102

The semiconductor device 1 is configured to be capable of dynamically switching the CPU to be operated between the CPU 101 and the CPU 102.

For example, when the connection destination of the power supply circuit 110 is the CPU 101, if the temperature sensor 109 detects that a temperature of the CPU 101 is equal to or higher than a predetermined temperature, leakage current of the CPU 101 in which a larger number of LVt cells is used is likely to increase. Accordingly, the semiconductor device 1 switches the CPU to be operated from the CPU 101 to the CPU 102 in which a larger number of HVt cells is used.

First, the CPU 101 updates the frequency setting information stored in the MRAM 105 from 800 MHz to 400 MHz. That is, the CPU 101 updates the frequency setting information stored in the MRAM 105 to information that instructs switching of the connection destination of the power supply circuit 110 from the CPU 101 to the CPU 102.

Subsequently, the control circuit 108 places the CPU 102 and the peripheral circuit 107 into a reset state based on an instruction from the CPU101, performs initial setting of the peripheral circuit 107 based on trimming information and the like read from the MRAM 105, and connects the power supply circuit 110 to either the CPU 101 or the CPU 102 based on the frequency setting information read from the MRAM 105. Specifically, the control circuit 108 switches the connection destination of the power supply circuit 110 from the CPU 101 to the CPU 102 based on the frequency setting information read from the MRAM 105. Thereafter, the control circuit 108 releases the reset of the CPU 102 and the peripheral circuit 107 and supplies a clock signal, thereby operating the system of the semiconductor device 1.

For example, when the connection destination of the power supply circuit 110 is the CPU 102, if the temperature sensor 109 detects that a temperature of the CPU 101 is lower than the predetermined temperature, leakage current of the CPU 101, in which a larger number of LVt cells are used, becomes small. Accordingly, the semiconductor device 1, for example, when a higher operating speed is desired, switches the CPU to be operated from the CPU 102 to the CPU 101.

First, the CPU 102 updates the frequency setting information stored in the MRAM 105 to information that instructs switching of the connection destination of the power supply circuit 110 from the CPU 102 to the CPU 101. Specifically, the CPU 102 updates the frequency setting information stored in the MRAM 105 from 400 MHz to 800 MHz.

Subsequently, the control circuit 108 places the CPU 101 and the peripheral circuit 107 into the reset state based on an instruction from the CPU 102, performs initial setting of the peripheral circuit 107 based on trimming information and the like read from the MRAM 105, and connects the power supply circuit 110 to either the CPU 101 or the CPU 102 based on the frequency setting information read from the MRAM 105. Specifically, the control circuit 108 switches the connection destination of the power supply circuit 110 from the CPU 102 to the CPU 101 based on the frequency setting information read from the MRAM 105. Thereafter, the control circuit 108 releases the reset of the CPU 101 and the peripheral circuit 107 and supplies a clock signal, thereby operating the system of the semiconductor device 1.

As described above, the semiconductor device 1 according to the present disclosure switches operation between the CPU 101, in which a larger number of LVt cells are used, and the CPU 102, in which a larger number of HVt cells are used, thereby implementing high-speed operation under low-temperature conditions while reducing leakage current particularly under high-temperature conditions. That is, the semiconductor device 1 according to the present disclosure can implement high-speed operation while reducing leakage current. The design of the semiconductor device 1 according to the present disclosure is easy, since it only requires addition of the CPU 102, the selectors SEL11 and SEL12, and the switch SW12 to the configuration of the semiconductor device 50. A program designer can easily design the semiconductor device 1 without being conscious that two CPUs exist.

It should be noted that a plurality of semiconductor devices 1 may be shipped as products having a plurality of different maximum operating frequencies. For example, among a plurality of semiconductor devices 1, a semiconductor device 1a having a maximum operating frequency of 800 MHz and a semiconductor device 1b having a maximum operating frequency of 400 MHz may be shipped as different products, respectively.

In this case, the MRAM 105 further stores, in a non-public storage region, a permission flag indicating whether or not updating of frequency setting information (power supply connection information) is permitted. For example, when the permission flag is “1” (active), updating of the frequency setting information is permitted, and when the permission flag is “0” (inactive), updating of the frequency setting information is not permitted.

For example, when the semiconductor device 1a having a maximum operating frequency of 800 MHz is shipped as a product, “800 MHz” is written into the MRAM 105 as frequency setting information, and the permission flag is set to “1” indicating permission for updating. Further, when the semiconductor device 1b having a maximum operating frequency of 400 MHz is shipped as a product, “400 MHz” is written into the MRAM 105 as frequency setting information, and the permission flag is set to “0” indicating prohibition of updating.

### Semiconductor Device 60 in Conceptual Stage Before Second Embodiment

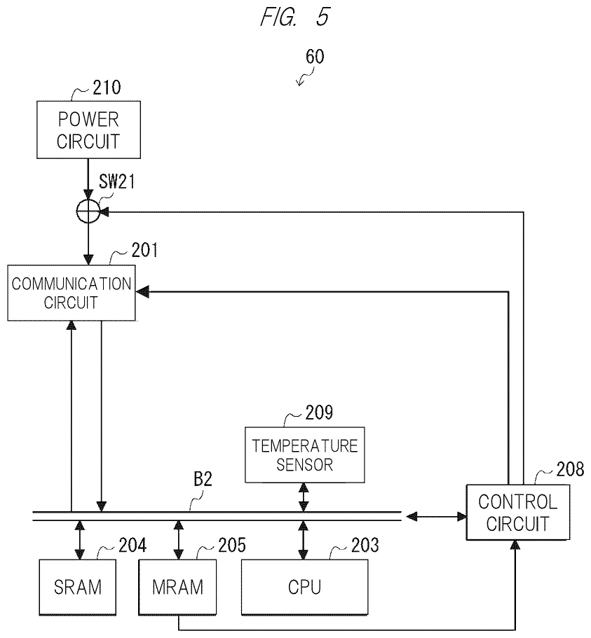

FIG. 5 is a block diagram illustrating a configuration example of a semiconductor device 60 in a conceptual stage. The semiconductor device 60 is, for example, an MCU equipped with a communication circuit.

Specifically, the semiconductor device 60 includes a communication circuit 201, a CPU 203, an SRAM 204, an MRAM 205, a control circuit 208, a temperature sensor 209, a power supply circuit 210, a bus B2, and a switch SW21. The temperature sensor 209 detects a temperature of the semiconductor device 60. More specifically, the temperature sensor 209 detects a temperature of the communication circuit 201.

The CPU 203 is connected via the bus B2 to the SRAM 204, the MRAM 205, the control circuit 208, the temperature sensor 209, and the communication circuit 201. The switch SW21 is provided between the power supply circuit 210 and the communication circuit 201. The communication circuit 201 is used for communication with the outside.

When transmitting data to the outside of the semiconductor device 60, the CPU 203 and the communication circuit 201 perform the following operations. First, the CPU 203 performs initial setting for the communication circuit 201, such as communication speed setting and address setting of a transmission buffer. Thereafter, the CPU 203 writes transmission-unit data into the transmission buffer of the communication circuit 201, and then sets a transmission start instruction register of the communication circuit 201. As a result, the communication circuit 201 transmits the written data to the outside of the semiconductor device 60. Thereafter, the CPU 203 monitors a transmission completion flag of the communication circuit 201 and waits for transmission completion.

The control circuit 208 controls on and off of the switch SW21 based on setting information read from a predetermined register. When the switch SW21 is turned on, power is supplied from the power supply circuit 210 to the communication circuit 201, thereby enabling operation of the communication circuit 201. On the other hand, when the switch SW21 is turned off, power supply from the power supply circuit 210 to the communication circuit 201 is cut off, thereby reducing leakage current of the communication circuit 201.

Here, the communication circuit 201 is configured using more LVt cells than HVt cells in order to implement high-speed operation. In other words, the communication circuit 201 is configured using more MOS transistors having a threshold voltage of LVt than MOS transistors having a threshold voltage of HVt. Therefore, in the communication circuit 201, an operating speed is high (that is, the maximum operating frequency is large), but leakage current becomes large. Particularly, due to recent miniaturization of processes, the leakage current becomes remarkably large as the temperature increases. However, in the communication circuit 201 dominated by LVt cells, even if the operating frequency is lowered at a high temperature, only dynamic current associated with switching is reduced, and the remarkably increased leakage current is not reduced. Accordingly, although the communication circuit 201 is suitable for high-speed operation under low-temperature conditions, it may not be suitable for operation with low power consumption under high-temperature conditions. In the present disclosure, a case where a maximum operating frequency of the communication circuit 201 is 800 MHz will be described as an example.

Thus, the semiconductor device 60 at the conceptual stage can implement high-speed operation under low-temperature conditions, but has a problem in that leakage current increases particularly under high-temperature conditions. Accordingly, a semiconductor device 2 according to the present disclosure has been provided, which solves such a problem, and which can implement high-speed operation under low-temperature conditions while reducing leakage current particularly under high-temperature conditions.

### Second Embodiment

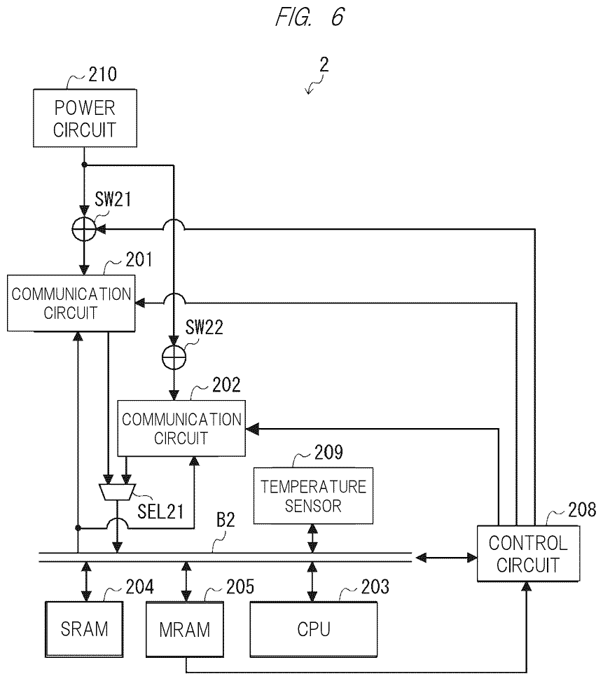

FIG. 6 is a block diagram illustrating a configuration example of a semiconductor device 2 according to a second embodiment. The semiconductor device 2 is, for example, an MCU equipped with a communication circuit.

The semiconductor device 2 further includes a communication circuit 202, a selector SEL21, and the switch SW22, in comparison with the semiconductor device 60. Specifically, the semiconductor device 2 includes a communication circuit (first electronic circuit) 201, a communication circuit (second electronic circuit) 202, a CPU 203, an SRAM 204, an MRAM 205, a control circuit 208, a temperature sensor 209, a power supply circuit (power supply) 210, a bus B2, a selector SEL21, and switches SW21 and SW22.

The communication circuit 202 has the same logical configuration as the communication circuit 201. The communication circuit 202 is configured using a plurality of LVt cells and a plurality of HVt cells, similarly to the communication circuit 201. However, a ratio occupied by the HVt cells among a plurality of logic cells used in the communication circuit 202 is greater than that in the communication circuit 201. Therefore, in the communication circuit 202, an operating speed becomes slower than that of the communication circuit 201 (that is, in the communication circuit 202, a maximum operating frequency becomes smaller than that of the communication circuit 201), but leakage current becomes smaller than that of the communication circuit 201. Accordingly, in the communication circuit 202, an increase in leakage current, which has become remarkable as temperature increases, is suppressed. In the present disclosure, a case where a maximum operating frequency of the communication circuit 202 is 400 MHz will be described as an example.

The switch SW21 is provided between the power supply circuit 210 and the communication circuit 201, and switches on and off based on a control signal from the control circuit 208. The switch SW22 is provided between the power supply circuit 210 and the communication circuit 202, and switches on and off based on a control signal from the control circuit 208. The switches SW21 and SW22 constitute a power supply connection portion, and are complementarily switched on and off based on the control signals from the control circuit 208 when the operation mode is the normal operation mode, and are both switched off based on the control signals from the control circuit 208 when the operation mode is the standby mode.

The selector SEL21 selects one of a signal from the communication circuit 201 to the bus B2 and a signal from the communication circuit 202 to the bus B2, and outputs the selected signal to the bus B1. A signal from the bus B1 is input to both the communication circuit 201 and the communication circuit 202.

The MRAM 205 stores frequency setting information. Here, the frequency setting information refers to information on a maximum operating frequency required for a communication circuit. The frequency setting information can also be referred to as power supply connection information that determines the communication circuit to which the power supply circuit 210 is to be connected among the communication circuit 201 and the communication circuit 202.

The control circuit 208, for example, upon receiving an instruction from the CPU 203, connects the power supply circuit 210 to one of the communication circuit 201 and the communication circuit 202 based on the frequency setting information read from the MRAM 205. Specifically, the control circuit 208 outputs control signals corresponding to the frequency setting information read from the MRAM 205 to the switches SW21 and SW22, and the selector SEL21. As a result, the switches SW21 and SW22 connect the communication circuit corresponding to the frequency setting information to the power supply circuit 210 among the communication circuit 201 and the communication circuit 202. In addition, the selector SEL21 connects a signal line between the communication circuit connected to the power supply circuit 210 and the bus B2. Thereafter, the control circuit 208 operates a communication function of the semiconductor device 2 by resetting the communication circuit connected to the power supply circuit 210 and then supplying a clock signal.

In the present disclosure, the maximum operating frequency of the communication circuit 201 is 800 MHz, and the maximum operating frequency of the communication circuit 202 is 400 MHz. Therefore, when “800 MHz” is set in the MRAM 205 as frequency setting information, the control circuit 208 controls the switch SW21 to be turned on and controls the switch SW22 to be turned off. That is, a power supply connection portion including the switches SW21 and SW22 selects the communication circuit 201 as a connection destination of the power supply circuit 210. As a result, a power supply voltage is supplied from the power supply circuit 210 to the communication circuit 201. At this time, the selector SEL21 selects, from among a signal from the communication circuit 201 to the bus B2 and a signal from the communication circuit 202 to the bus B2, the signal from the communication circuit 201 selected as the connection destination of the power supply circuit 210, and outputs the selected signal to the bus B2.

On the other hand, when “400 MHz” is set in the MRAM 205 as frequency setting information, the control circuit 208 controls the switch SW21 to be turned off and controls the switch SW22 to be turned on. That is, the power supply connection portion including the switches SW21 and SW22 selects the communication circuit 202 as the connection destination of the power supply circuit 210. As a result, a power supply voltage is supplied from the power supply circuit 210 to the communication circuit 202. At this time, the selector SEL21 selects, from among a signal from the communication circuit 201 to the bus B2 and a signal from the communication circuit 202 to the bus B2, the signal from the communication circuit 202 selected as the connection destination of the power supply circuit 210, and outputs the selected signal to the bus B2.

### Method of Dynamically Switching Communication Circuit 201 and Communication Circuit 202

The semiconductor device 2 is configured to be capable of dynamically switching the communication circuit to be operated between the communication circuit 201 and the communication circuit 202.

For example, when the connection destination of the power supply circuit 210 is the communication circuit 201, if the temperature sensor 209 detects that a temperature of the communication circuit 201 is equal to or higher than a predetermined temperature, leakage current of the communication circuit 201, in which a larger number of LVt cells are used, may increase. Therefore, the semiconductor device 2 switches the communication circuit to be operated from the communication circuit 201 to the communication circuit 202, in which a larger number of HVt cells are used. A specific description will be given below.

When the temperature sensor 209 detects that the temperature of the communication circuit 201 is equal to or higher than the predetermined temperature, first, the CPU 203 waits until a transmission of data being transmitted is completed with a transmission completion flag of the communication circuit 201 becoming active. Thereafter, the CPU 203 updates the frequency setting information stored in the MRAM 205 from 800 MHz to 400 MHz. That is, the CPU 203 updates the frequency setting information stored in the MRAM 205 to information that instructs switching of the connection destination of the power supply circuit 210 from the communication circuit 201 to the communication circuit 202.

Thereafter, the control circuit 208, upon receiving an instruction from the CPU 203, connects the power supply circuit 210 to one of the communication circuit 201 and the communication circuit 202 based on the frequency setting information read from the MRAM 205. Specifically, the control circuit 208 switches the connection destination of the power supply circuit 210 from the communication circuit 201 to the communication circuit 202 based on the frequency setting information read from the MRAM 205. Thereafter, the control circuit 208 resets the communication circuit 202 and then starts a communication operation by the communication circuit 202.

Further, for example, when the connection destination of the power supply circuit 210 is the communication circuit 202, if the temperature sensor 209 detects that the temperature of the communication circuit 201 is lower than a predetermined temperature, leakage current of the communication circuit 201, in which a larger number of LVt cells are used, becomes small. Therefore, the semiconductor device 2, for example, when a higher operating speed is desired, switches the communication circuit to be operated from the communication circuit 202 to the communication circuit 201. A specific description will be given below.

When the temperature sensor 209 detects that the temperature of the communication circuit 201 is lower than the predetermined temperature, first, the CPU 203 waits until a transmission of data being transmitted is completed with a transmission completion flag of the communication circuit 201 becoming active. Thereafter, the CPU 203 updates the frequency setting information stored in the MRAM 205 from 400 MHz to 800 MHz. That is, the CPU 203 updates the frequency setting information stored in the MRAM 205 to information that instructs switching of the connection destination of the power supply circuit 210 from the communication circuit 202 to the communication circuit 201.

Thereafter, the control circuit 208, upon receiving an instruction from the CPU 203, connects the power supply circuit 210 to one of the communication circuit 201 and the communication circuit 202 based on the frequency setting information read from the MRAM 205. Specifically, the control circuit 208 switches the connection destination of the power supply circuit 210 from the communication circuit 202 to the communication circuit 201 based on the frequency setting information read from the MRAM 205. Thereafter, the control circuit 208 resets the communication circuit 201 and then starts a communication operation by the communication circuit 201.

As described above, the semiconductor device 2 according to the present disclosure switches operation between the communication circuit 201, in which a larger number of LVt cells are used, and the communication circuit 202, in which a larger number of HVt cells are used, thereby implementing high-speed operation under low-temperature conditions while reducing leakage current particularly under high-temperature conditions. That is, the semiconductor device 2 according to the present disclosure can implement high-speed operation while reducing leakage current. The design of the semiconductor device 2 according to the present disclosure is easy, since it only requires addition of the communication circuit 202, the selector SEL21, and the switch SW22 to the configuration of the semiconductor device 60. In addition, since address spaces of the communication circuit 201 and the communication circuit 202 coincide with each other, a program designer can easily design the semiconductor device 2 without being conscious that two communication circuits exist.

In the present disclosure, cases have been described in which the semiconductor device dynamically switches operation between the CPU 101, in which a larger number of LVt cells are used, and the CPU 102, in which a larger number of HVt cells are used, or dynamically switches operation between the communication circuit 201, in which a larger number of LVt cells are used, and the communication circuit 202, in which a larger number of HVt cells are used. However, the present disclosure is not limited thereto. The semiconductor device may be provided with a circuit other than a CPU or a communication circuit, including a circuit in which a larger number of LVt cells are used and a circuit in which a larger number of HVt cells are used, and may dynamically switch operation between them. In addition, the configuration of the CPU 101 and the CPU 102 and the configuration of the communication circuit 201 and the communication circuit 202 may be used in combination. Furthermore, the dynamic switching is not limited to being performed based on a detection result of the temperature sensor, but may also be performed based on other factors.

As described above, the invention made by the present inventor has been specifically described based on embodiments. However, it goes without saying that the present invention is not limited to the embodiments already described, and various modifications may be made without departing from the spirit of the invention.

The present disclosure can implement a part or all of processes of each of the semiconductor devices 1 and 2 by causing a CPU to execute a computer program.

The above-described program includes instructions (or software code) for causing a computer to perform one or more functions described in the embodiments when loaded into the computer. The program may be stored in a non-transitory computer-readable medium or a tangible storage medium. By way of example and not limitation, the computer-readable medium or the tangible storage medium includes a Random-Access Memory (RAM), a Read-Only Memory (ROM), a flash memory, a Solid-State Drive (SSD), or other memory technologies, a CD-ROM, a Digital Versatile Disc (DVD), a Blu-ray (registered trademark) disc, or other optical disc storages, a magnetic cassette, a magnetic tape, a magnetic disk storage, or other magnetic storage devices. The program may also be transmitted over a transitory computer-readable medium or a communication medium. By way of example and not limitation, the transitory computer-readable medium or the communication medium includes propagating signals in electrical, optical, acoustic, or other forms.

What is claimed is:

1. A semiconductor device comprising:
a first electronic circuit including a first semiconductor element group having a first threshold voltage, and a second semiconductor element group having a second threshold voltage higher than the first threshold voltage;
a second electronic circuit having a same logical configuration as the first electronic circuit, and in which a ratio occupied by the second semiconductor element group among the first semiconductor element group and the second semiconductor element group is greater than that in the first electronic circuit;
a power supply connection portion that connects one of the first electronic circuit and the second electronic circuit to a power supply;
a storage unit that stores power supply connection information; and
a control circuit that controls the power supply connection portion to connect the power supply to one of the first electronic circuit and the second electronic circuit selected based on the power supply connection information read from the storage unit.

2. The semiconductor device according to claim 1, further comprising
a temperature sensor that detects a temperature of the first electronic circuit,
wherein, when a connection destination of the power supply is the first electronic circuit, if the temperature sensor detects that a temperature of the first electronic circuit is equal to or higher than a predetermined temperature, the control circuit controls the power supply connection portion so as to switch the connection destination of the power supply from the first electronic circuit to the second electronic circuit based on the power supply connection information read from the storage unit.

3. The semiconductor device according to claim 2,
wherein, when the connection destination of the power supply is the first electronic circuit, if the temperature sensor detects that the temperature of the first electronic circuit is equal to or higher than the predetermined temperature, the first electronic circuit updates the power supply connection information stored in the storage unit to information that instructs switching of the connection destination of the power supply from the first electronic circuit to the second electronic circuit.

4. The semiconductor device according to claim 3,
wherein, when the connection destination of the power supply is the second electronic circuit, if the temperature sensor detects that the temperature of the first electronic circuit is lower than the predetermined temperature, the control circuit controls the power supply connection portion so as to switch the connection destination of the power supply from the second electronic circuit to the first electronic circuit based on the power supply connection information read from the storage unit.

5. The semiconductor device according to claim 4,
wherein, when the connection destination of the power supply is the second electronic circuit, if the temperature sensor detects that the temperature of the first electronic circuit is lower than the predetermined temperature, the second electronic circuit updates the power supply connection information stored in the storage unit to information that instructs switching of the connection destination of the power supply from the second electronic circuit to the first electronic circuit.

6. The semiconductor device according to claim 1,
wherein the first electronic circuit and the second electronic circuit are both arithmetic processing circuits that execute instructions of a computer-readable storage medium.

7. The semiconductor device according to claim 1,
wherein the storage unit further stores a permission flag indicating whether or not updating of the power supply connection information is permitted, and
wherein the power supply connection information is configured to be updatable only when the permission flag is active.

8. The semiconductor device according to claim 1,
wherein the first electronic circuit and the second electronic circuit are both communication circuits that perform communication with outside.

9. The semiconductor device according to claim 1,
wherein the first electronic circuit is configured to operate at a maximum operating frequency larger than that of the second electronic circuit.

10. The semiconductor device according to claim 9,
wherein the power supply connection information includes information on a maximum operating frequency.

11. The semiconductor device according to claim 1,
wherein the storage unit is a non-volatile memory.

12. The semiconductor device according to claim 1,
wherein, when an operation mode is a normal operation mode, the control circuit controls the power supply connection portion so as to connect the power supply to one of the first electronic circuit and the second electronic circuit selected based on the power supply connection information read from the storage unit, and
wherein, when the operation mode is a standby mode, the control circuit controls the power supply connection portion so as to cut off connection of each of the first electronic circuit and the second electronic circuit with the power supply.

13. A method for controlling a semiconductor device, wherein the semiconductor device comprises:
a first electronic circuit including a first semiconductor element group having a first threshold voltage, and a second semiconductor element group having a second threshold voltage higher than the first threshold voltage; and
a second electronic circuit having a same logical configuration as the first electronic circuit, and in which a ratio occupied by the second semiconductor element group among the first semiconductor element group and the second semiconductor element group is greater than that in the first electronic circuit,
the method for controlling the semiconductor device comprising:
reading out power supply connection information stored in a storage unit; and
connecting one of the first electronic circuit and the second electronic circuit selected based on the read power supply connection information to a power supply.

14. The semiconductor device according to claim 13,
wherein, when a connection destination of the power supply is the first electronic circuit, if a temperature sensor detects that a temperature of the first electronic circuit is equal to or higher than a predetermined temperature, the connection destination of the power supply is switched from the first electronic circuit to the second electronic circuit based on the read power supply connection information.

15. A computer readable storage medium for control that causes a computer to execute control processing of a semiconductor device comprising:
a first electronic circuit including a first semiconductor element group having a first threshold voltage, and a second semiconductor element group having a second threshold voltage higher than the first threshold voltage; and
a second electronic circuit having a same logical configuration as the first electronic circuit, and in which a ratio occupied by the second semiconductor element group among the first semiconductor element group and the second semiconductor element group is greater than that in the first electronic circuit,
the computer readable storage medium for control causing the computer to execute processes of:
reading out power supply connection information stored in a storage unit; and
connecting one of the first electronic circuit and the second electronic circuit selected based on the read power supply connection information to a power supply.

16. The computer readable storage medium for control according to claim 15,
wherein, in the process of connecting one of the first electronic circuit and the second electronic circuit to the power supply, when a connection destination of the power supply is the first electronic circuit, if a temperature sensor detects that a temperature of the first electronic circuit is equal to or higher than a predetermined temperature, the connection destination of the power supply is switched from the first electronic circuit to the second electronic circuit based on the read power supply connection information.
